(19) United States
(12) Patent Application Publication
(10) Pub. No.: US 2009/0104460 A1
(43) Pub. Date: Apr. 23, 2009

(54) Silicon-based decorative coatings

(76) Inventor: Gary Barone, State College, PA (US)

Correspondence Address: John F.A. Earley III;Harding, Earley, Follmer & Frailey, Post Office Box 750 1288 Valley Forge Road, 86 The Commons at Valley Forge East, Valley Forge, PA, 19482-0750, US

(21) Appl. No.: 11/981,772

(22) Filed: Oct. 31, 2007

Related U.S. Application Data
(60) Provisional application No. 60/855,467, filed on Oct. 31, 2006.

(51) Int. Cl. B32B 9/04; C23C 16/00

(52) U.S. Cl. 428/447; 427/255.23; 427/255.27

(57) ABSTRACT

An article of manufacture, or a component part thereof, having a decorative coating comprising a coating of silicon or a coating of hydrogenated amorphous silicon functionalized with a binding agent. A method of applying a decorative coating to the surface of an article of manufacture, or to the surface of a component part of an article of manufacture, by depositing a silicon coating on the surface to be decorated using silicon hydride gas, or by depositing a coating of hydrogenated amorphous silicon on the surface to be decorated and functionalizing the hydrogenated amorphous silicon coating with a binding agent.

### BACKGROUND OF THE INVENTION

1. Field of the Invention

This invention relates to decorative coatings, and more particularly concerns silicon-based decorative coatings applied to substrates.

2. Description of the Prior Art

In today's marketplace, many times it is important to provide a decorative coating to an article of manufacture, or to a component part or parts of an article of manufacture. This is especially true in the automotive industry and with consumable items (e.g., watches, pens, etc.). Decorative coatings also are applicable for articles of manufacture (and component parts thereof) used in the aerospace industry.

### SUMMARY OF THE INVENTION

It is an object of this invention to provide a method of providing a decorative coating onto an article of manufacture, or to a component part or parts of an article of manufacture.

It is another object of this invention to provide an article of manufacture having a decorative coating thereon.

Further, it is an object of this invention to provide a component part of an article of manufacture, the component part having a decorative coating applied thereto.

These and other objects are accomplished by the present invention which is described in detail below.

### BRIEF DESCRIPTION OF THE DRAWINGS

FIG. 1 is a schematic illustration of an article of manufacture (or a component part of the article of manufacture) treated in accordance with the present invention.

FIG. 2 is a schematic illustration of an article of manufacture (or a component part of the article of manufacture) treated in accordance with another embodiment of the present invention.

### DETAILED DESCRIPTION

In accordance with the present invention, a first preferred method is provided for applying a decorative coating to the surface of an article of manufacture or to a surface of a component part of an article of manufacture. In accordance with the present invention, this inventive method of coating the surface of an article of manufacture with a decorative coating, or coating the surface of a component part of the article of manufacture, is accomplished using substantially the steps of the method of passivating the surface of the gas storage vessel or component of gas storage and transfer system as disclosed in Restek Corporation U.S. Pat. No. 6,511,760, which is incorporated herein by reference. However, in contrast to the steps of the method set out in Restek Corporation U.S. Pat. No. 6,511,760, the surface being acted upon in the present invention is the outer surface of an article of manufacture (or a component part thereof) onto which it is desired to apply a decorative coating, rather than the interior surface of a gas storage vessel or the interior surface of a component of a gas storage and transfer system, to achieve a decorative coating on the article of manufacture or the component part of an article of manufacture.

In accordance with this preferred embodiment of the invention, the method of coating to the surface of an article of manufacture with a decorative coating is accomplished by:
a) placing the article of manufacture in a treatment environment (e.g., treatment chamber) for treatment;
b) dehydrating the surface of the article of manufacture;
c) evacuating the treatment environment;
d) introducing a silicon hydride gas into the treatment environment to contact the surface of the article of manufacture;
e) heating and pressurizing the silicon hydride gas in the treatment environment;
f) depositing a layer of silicon on the surface of the article of manufacture;
g) controlling the duration of the silicon depositing step to prevent the formation of silicon dust;
h) purging the treatment environment with an inert gas to remove the silicon hydride gas;
i) repeating steps c-h until a desired decorative coating is obtained on the surface of the article of manufacture desired to be provided with the decorative coating;
j) evacuating the treatment environment; and,
k) cooling the article of manufacture having the decorative coating formed thereon to room temperature.
   The process conditions (e.g., temperatures, pressure conditions, length (time duration) of steps, composition of the silicon hydride gas, etc.) used in this method of the present invention are the same as those used for the steps of the method described in Restek Corporation U.S. Pat. No. 6,511,760, which are incorporated herein by reference, with the article of manufacture to be provided with a decorative coating being substituted for the surface of the gas storage vessel or gas transfer component being treated in the method of Restek Corporation U.S. Pat. No. 6,511,760.

If it is desired to only provide a decorative coating to only a component part of the article of manufacture rather than to the entire article of manufacture, just the component part onto which a decorative coating is desired to be applied is subjected to the process set out above.

In accordance with the present invention, a second preferred method is provided for applying a decorative coating to the surface of an article of manufacture or to a surface of a component part of an article of manufacture. In accordance with the present invention, this second inventive method of coating the surface of an article of manufacture with a decorative coating, or coating the surface of a component part of the article of manufacture, is accomplished using substantially the steps of the method of passivating the surface of a substrate to protect against corrosion or the undesirable effects on a vacuum atmosphere as disclosed in Restek Corporation U.S. Pat. No. 7,070,833, which is incorporated herein by reference. However, in contrast to the steps of the method set out in Restek Corporation U.S. Pat. No. 7,070,833, the surface being acted upon in the present invention is the outer surface of an article of manufacture (or a component part thereof) onto which it is desired to apply a decorative coating, rather than the surface of a substrate desired to be protected against corrosion or the undesirable effects on a vacuum atmosphere, to achieve a decorative coating on the article of manufacture or the component part of an article of manufacture.

In accordance with this second preferred embodiment of the invention, the method of coating the surface of an article of manufacture with a decorative coating is accomplished by:
a) placing the article of manufacture in a treatment environment (e.g., treatment chamber) for treatment;
b) dehydrating the surface of the article of manufacture;
c) evacuating the treatment environment;
d) introducing a silicon hydride gas into the treatment environment to contact the surface of the article of manufacture;
e) heating and pressurizing the silicon hydride gas prior to, during or after the introduction of silicon hydride gas in the treatment environment;
f) depositing a layer of silicon on the surface of the article of manufacture;
g) controlling the duration of the silicon depositing step, the pressure of the silicon hydride gas, and the presence of contaminants on the surface of the article of manufacture to prevent the formation of silicon dust;
h) cooling the article of manufacture to a lower temperature and maintaining the article of manufacture at a lower temperature for a period of time,
i) purging the treatment environment with an inert gas to remove the silicon hydride gas;
j) repeating steps c-j until a desired decorative coating is obtained on the surface of the article of manufacture desired to be provided with the decorative coating;
k) evacuating the treatment environment; and,
l) cooling the article of manufacture having the decorative coating formed thereon to room temperature.
   The process conditions (e.g., temperatures, pressure conditions, length (time duration) of steps, composition of the silicon hydride gas, etc.) used in this second method of the present invention are the same as those used for the steps of the method described in Restek Corporation U.S. Pat. No. 7,070,833, which are incorporated herein by reference, with the article of manufacture to be provided with a decorative coating being substituted for the surface of the substrate being passivated in the method of Restek Corporation U.S. Pat. No. 7,070,833.

If it is desired to only provide a decorative coating to only a component part of the article of manufacture rather than to the entire article of manufacture, just the component part onto which a decorative coating is desired to be applied is subjected to the second process set out above.

In accordance with the present invention, a third preferred method is provided for applying a decorative coating to the surface of an article of manufacture or to a surface of a component part of an article of manufacture. In accordance with the present invention, this third inventive method of coating the surface of an article of manufacture with a decorative coating, or coating the surface of a component part of the article of manufacture, is accomplished using substantially the steps of the method of modifying the surface properties of a substrate such as the inner surface of a gas storage vessel or component of gas storage and transfer system as disclosed in Restek Corporation U.S. Pat. No. 6,444,326, which is incorporated herein by reference. However, in contrast to the steps of the method set out in Restek Corporation U.S. Pat. No. 6,444,326, the surface being acted upon in the present invention is the outer surface of an article of manufacture (or a component part thereof) onto which it is desired to apply a decorative coating, rather than the surface being modified in accordance with the method of Restek Corporation U.S. Pat. No. 6,444,326, to achieve a decorative coating on the article of manufacture or the component part of an article of manufacture.

In accordance with this third preferred embodiment of the invention, the method of coating to the surface of an article of manufacture with a decorative coating is accomplished by:
a) placing the article of manufacture in a treatment environment (e.g., treatment chamber) for treatment;
b) depositing a coating of hydrogenated amorphous silicon on the surface of the article of manufacture; and
c) functionalizing the coated article of manufacture by exposing the coated article of manufacture to a binding reagent having at least one unsaturated hydrocarbon group at an effective pressure and elevated temperature for an effective length of time.
   Preferably, this third method also includes the steps of initially cleaning the article of manufacture by heating it to a temperature between to about 100 degrees C. and about 600 C. for a time period ranging from few minutes to about 15 hours before exposing the article of manufacture to hydrogenated amorphous silicon, quenching residual silicon radicals in the hydrogenated amorphous silicon coating either before or after functionalizing the coated article of manufacture, and/or exposing the article of manufacture to oxygen prior to or contemporaneously with the hydrosilylation step.

The process conditions (e.g., temperatures, pressure conditions, length (time duration) of steps, composition of the silicon hydride gas, etc.) used in this third method of the present invention are the same as those used for the steps of the method described in Restek Corporation U.S. Pat. No. 6,444,326 which are incorporated herein by reference, with the article of manufacture to be provided with a decorative coating being substituted for the surface being modified in the method of Restek Corporation U.S. Pat. No. 6,444,326.

If it is desired to only provide a decorative coating to only a component part of the article of manufacture rather than to the entire article of manufacture, just the component part onto which a decorative coating is desired to be applied is subjected to the third process set out above.

The outer surface of the article of manufacture (or a component part thereof) which is to receive the decorative coating in accordance with the invention may comprise metal (ferrous and non-ferrous), glass, carbon, copper, quartz, nickel-containing ferrous alloys, titanium, aluminum, and ceramics.

The present invention pertains to articles of manufacture and component parts thereof onto which a decorative coating is desired to be applied. The present invention is particularly useful in the automotive industry for use on articles of manufacture and component parts thereof used in the automotive industry. The present invention also has particular applicability with respect to the manufacturing of consumable items (e.g., watches, pens, etc.), which benefit from a decorative coating. The present invention also is useful for providing a decorative coating to articles of manufacture (and component parts thereof) used in the aerospace industry.

Preferably, the silicon-based decorative coatings of the present invention have a thickness or depth preferably in the range of 0.01 microns to 20 microns.

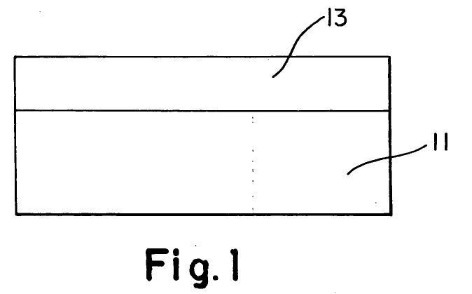

Turning to the drawings, FIG. 1 illustrates schematically an article of manufacture 11 (or a component part thereof) which has received a decorative coating 13 in accordance with the first and second methods of the present invention discussed above.

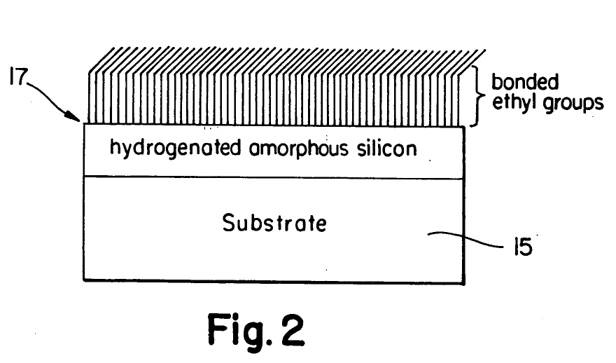

FIG. 2 illustrates schematically an article 15 of manufacture (or a component part of an article of manufacture) having a silicon-based decorative coating 17 applied thereto in accordance with the third preferred method of the invention discussed above.

The unique methods of providing a silicon-based decorative coating create advantageous optical properties when the decorative coating is applied over an article of manufacture (or a component part of an article of manufacture) such as ferrous and non-ferrous substrates. The decorative coating of the invention also has the benefits set out in Restek Corporation U.S. Pat. Nos. 6,511,760, 7,070,833, and 6,444,326 relating to passivating a surface of and modifying the surface properties of a substrate.

1. A method of coating an outer surface of object with a decorative coating, comprising the steps of
a) placing an object having an outer surface to be coated with a decorative coating in a treatment environment (e.g., treatment chamber) for treatment;
b) dehydrating the outer surface of the object;
c) evacuating the treatment environment;
d) introducing a silicon hydride gas into the treatment environment to contact the outer surface of the object;
e) heating and pressurizing the silicon hydride gas in the treatment environment;
f) depositing a layer of silicon on the outer surface of the object;
g) controlling the duration of the silicon depositing step to prevent the formation of silicon dust;
h) purging the treatment environment with an inert gas to remove the silicon hydride gas;
i) repeating steps c-h until a desired decorative coating is obtained on the outer surface of the object desired to be provided with the decorative coating;
j) evacuating the treatment environment; and,
k) cooling the object having the decorative coating formed thereon to room temperature.

2. A method of coating an outer surface of an object with a decorative coating, comprising the steps of
a) placing an object having an outer surface to be coated with a decorative coating in a treatment environment (e.g., treatment chamber) for treatment;
b) dehydrating the outer surface of the object;
c) evacuating the treatment environment;
d) introducing a silicon hydride gas into the treatment environment to contact the outer surface of the object;
e) heating and pressurizing the silicon hydride gas prior to, during or after the introduction of silicon hydride gas in the treatment environment;
f) depositing a layer of silicon on the outer surface of the object;
g) controlling the duration of the silicon depositing step, the pressure of the silicon hydride gas, and the presence of contaminants on the outer surface of the object to prevent the formation of silicon dust;
h) cooling the object to a lower temperature and maintaining the object at a lower temperature for a period of time,
i) purging the treatment environment with an inert gas to remove the silicon hydride gas;
j) repeating steps c-j until a desired decorative coating is obtained on the outer surface of the object desired to be provided with the decorative coating;
k) evacuating the treatment environment; and,
l) cooling the object having the decorative coating formed thereon to room temperature.

3. A method of coating the outer surface of an object with a decorative coating, comprising the steps of
a) placing an object having an outer surface to be coated with a decorative coating in a treatment environment (e.g., treatment chamber) for treatment;
b) depositing a coating of hydrogenated amorphous silicon on the outer surface of the object; and
c) functionalizing the coated object by exposing the coated object to a binding reagent having at least one unsaturated hydrocarbon group at an effective pressure and elevated temperature for an effective length of time.

4. The method of claim 3, further including
initially cleaning the object by heating it to a temperature between to about 100 degrees C. and about 600 C. for a time period ranging from few minutes to about 15 hours before exposing the object to hydrogenated amorphous silicon, quenching residual silicon radicals in the hydrogenated amorphous silicon coating either before or after functionalizing the coated object, and/or exposing the object to oxygen prior to or contemporaneously with the hydrosilylation step.

5. An object having an outer surface treated in accordance with the method of claim 1.

6. An object having an outer surface treated in accordance with the method of claim 2.

7. An object having an outer surface treated in accordance with the method of claim 3.

8. An object having an outer surface treated in accordance with the method of claim 4.
